(19) United States
(12) Patent Application Publication
(10) Pub. No.: US 2012/0028012 A1
(43) Pub. Date: Feb. 2, 2012

(54) MULTILAYER COATING

(75) Inventors: John Nicholls, Buckinghamshire (GB); Ken Lawson, Bedfordshire (GB); Jeff Rao, Bedford (GB); Alex Gorrupa, Worcestershire (GB)

(73) Assignees: CRANFIELD UNIVERSITY, Bedfordshire (GB); TEER COATINGS LIMITED, Worcestershire (GB)

(21) Appl. No.: 13/147,316

(22) PCT Filed: Jan. 28, 2010
(86) PCT No.: PCT/GB2010/000128

§ 371 Date: Oct. 4, 2011

(30) Foreign Application Priority Data
Feb. 2, 2009 (GB) 0901687.4

(51) Int. Cl. B32B 15/04; C23C 14/14; C23C 14/06; C23C 14/35

(52) U.S. Cl. 428/213; 428/336; 428/450; 428/469; 204/192.15

(57) ABSTRACT

A coating and a method of forming the same on a substrate is provided. The coating is provided with at least one ceramic material layer and at least one metal material layer. At least one of the materials used is a shape memory alloy so as to provide elasticity in the coating so as to allow any deformation of the same to be substantially recovered.

The present invention relates to a method of forming a coating, and the coating itself. A problem with existing coatings is that while they can be formed to have specific properties this may be to the detriment of other characteristics of the coating and this therefore restricts the usefulness of the coating to specific purposes.

It is known from U.S. Pat. Nos. 4,554,201, 4,895,770, 4,904,542 and 5,656,364 to produce multiple layered wear resistant coatings onto a substrate, where the layered systems are resistant to wear associated with metal cutting (U.S. Pat. No. 4,554,201 and U.S. Pat. No. 4,895,770), sliding wear or erosion (U.S. Pat. No. 4,904,542, U.S. Pat. No. 5,656,364).

It is know from both US (U.S. Pat. No. 5,656,364) and European patents (EP0366289A, EP0289173A) to produce multiple layer wear resistant coatings on the surface of a substrate using alternating layers of metallic material and the nitride, carbide or oxide of the metallic material. Specifically in patent EP02089173A the multiple layers consist of titanium and titanium nitride. In U.S. Pat. No. 4,904,542 the multiple layers consist of either titanium, zirconium, hafnium or tantalum plus nitrides of the chosen material. In U.S. Pat. No. 5,656,364 the multiple layers consist of titanium diboride and a metallic material with high elastic modulus, e.g. an alloy based on tungsten. U.S. Pat. No. 5,656,364 precludes the use of low elastic modulus materials, citing aluminium and titanium, for use in the erosion resistant multilayer coating system disclosed therein.

The aim of the present invention is to provide a coating which is elastic in characteristic in that deformation of the same is substantially recovered, whilst achieving a relatively hard wearing characteristic.

In a first aspect of the invention there is provided a wear resistant coating for a surface of a substrate, said coating having at least one metallic material layer and at least one ceramic material layer and having sufficient elasticity to provide protection against impact, erosion and/or cyclically loaded wear processes.

In one embodiment the coating consists of a plurality of metallic material and ceramic material layers. In one embodiment the said coating consists of at least four layers. Typically the layers of ceramic alternate with the layers of metallic material.

In one embodiment at least one of the metallic layers is formed from a ‘shape memory alloy’ which, typically, provides the required elastic properties.

In one embodiment the ceramic layer is any, or any combination, of a boride, carbide, nitride or oxide of metals from groups 4, 5 or 6, and/or aluminium or silicon. In accordance with one form of the invention there is provided a coating with an alloy layer and at least one ceramic layer formed from boride, carbide, nitride or oxide.

Typically, the metallic layer comprises an NiTi alloy and/or elements selected from nickel, titanium, chromium, aluminium, platinum, hafnium, zirconium, cobalt, copper, and/or yttrium to provide shape memory alloy properties, and preferably super-elastic behaviour.

In one embodiment the multi-layered coating is deposited at a temperature to aid the recrystallisation of the ‘shape memory alloy’ layer.

Typically the ceramic used is a boride, carbide, nitride or oxide of one of the alloying elements included in the ‘shape memory alloy’ material to ensure good chemical bonding between the respective layers.

In one embodiment an interfacial ceramic layer is deposited. In one embodiment the said interfacial layer is a boride, carbide, nitride or oxide of one of the alloying elements included in the ‘shape memory alloy’ material.

Typically the thickness of the ceramic layer(s) lies in the range 0.1 to 5.0 μm, preferably 0.3 to 3.0 μm.

In one embodiment the ceramic layer thickness is below the critical thickness of ceramic brittle fracture, defined as:

$${h}_{c} = \frac{E {ϒ}_{s}}{2 f \cdot {σ}^{2}}$$

where E is the ceramic elastic modulus, γs is the fracture surface energy for the ceramic, φ is the maximum tensile stress generated in the ceramic layers as a result of impact loading, and f is a geometric factor related to the contact geometry, typically 16 for a 1 μm thick ceramic layer with a modulus of 300 GPa.

In one embodiment the ceramic layer is itself a multiplicity of layers and each layer may be of different ceramic composition whereby the ceramic layer exhibits a super-lattice structure, which improves both its hardness and fracture resistance.

In a further aspect of the invention there is provided a method of forming an elastic coating on a substrate, said method including the steps of applying a plurality of layers of ceramic material and a plurality of layers of metallic material and wherein said layers of ceramic material alternate with the layers of metal material as the coating is formed.

In one embodiment at least one of the metal layers is formed from a shape memory alloy.

In one embodiment a sputtering process is used to supply the ceramic layer and preferably a closed field, unbalanced magnetron sputter ion plating (CFUBMSIP) is used, to improve the adhesion and structure/habit of the ceramic layer.

In one embodiment a sputter process is used to apply the metallic layer and preferably a closed field unbalanced magnetron sputter ion plating (CFUBMSIP) is used to improve the structure/habit of the metal layer.

In one embodiment the first ceramic layer is bonded to the substrate material by an adhesion layer that is not a ‘shape memory alloy’ but a metal or an alloy specifically chosen to aid bonding between the ceramic layer and the substrate. In one embodiment the adhesion layer is titanium and/or chromium or an alloy based on titanium or chromium.

Typically, the first metallic layer is designed to be an adhesion layer to enhance the bonding of the first ceramic layer, which, in turn, provides a diffusion barrier function.

Typically the shape memory alloy layer thickness is between 0.5× and 2.0× the ceramic layer thickness.

In one embodiment the plurality of layers extends to 25 repeat metal plus ceramic bi-layers, one of which is the metallic adhesion layer.

In accordance with one embodiment of the invention a wear resistant coating is formed of a plurality of alternating layers of metallic and ceramic materials. The two materials are typically selected to provide complimentary properties to the wear resistant coatings; one being hard but relatively brittle and the second having high ductility, plus super-elastic properties. The ductile super-elastic alloy is of the class of materials known as a ‘Shape memory alloy’. The preferred layer thickness should lie between 0.3 and 3.0 μm, with the ceramic thickness of any layer in the plurality of alternating layers never exceeding the critical defect size for ceramic brittle fracture.

A specific embodiment of the invention is now described with reference to the accompanying drawings; wherein

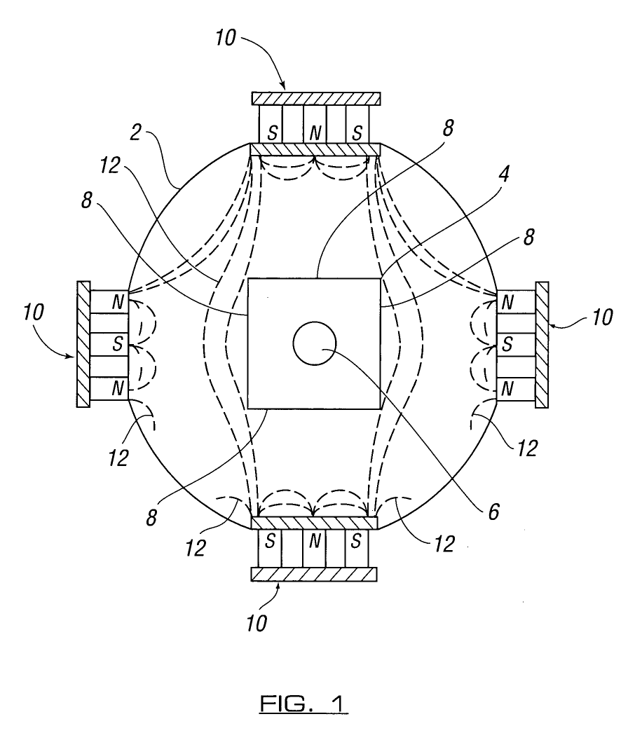

FIG. 1 illustrates a plan schematic view of apparatus which can be used; and

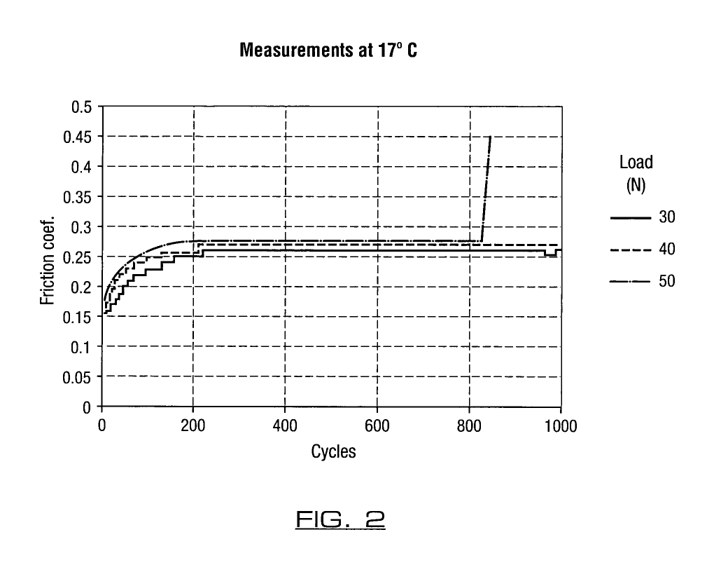

FIG. 2 illustrates one set of test results of a coating formed in accordance with the invention.

There is provided a wear resistant coating system for a substrate in accordance with the invention which is particularly useful where the coating is subject to dynamic, reciprocating, loading and/or rolling cycles. The elasticity of the coating means that any impact on the coating such as by an object propelled onto the coating or passing along the same and which causes deformation of the same can be absorbed, as the elasticity of the coating ensures that once the impacting article has been removed, at least some, and preferably all, of the deformation which has been caused, is recovered.

In one embodiment the impact loading cycles may result from multiple ballistic impact which, in conventional surfaces or coatings, cause an erosion effect introduced by particles impacting the coating substrate system. However in the coating created in the current invention, there is provided a multilayer erosion resistant coating system. In one embodiment the coatings can be used for gas turbine engine and/or steam turbine components, e.g. compressor blades within gas turbines and turbine blades in steam turbines where the adverse affects of impact loads are typically experienced. A second field with similar cyclic loads is a the rolling contact fatigue experienced in all bearing systems for highly loaded mechanical machines including automotive, aerospace, wind turbines and manufacturing applications.

A second field with similar loading cycles is the rolling contact fatigue experienced in all bearing systems, for highly loaded mechanical machines including automotive, aerospace, various manufacturing applications, power generation, precision machining and industrial manufacturing processes. FIG. 2 illustrates test results obtained from repeat wear tests over a number of cycles and at loads of 30 Newtons, 40 Newtons and 50 Newtons and in which the results for the friction co-efficient values show that the coating is resistant to fatigue streams and protects against rolling contact fatigue as the friction co-efficient value remain substantially consistent as the number of cycles increases.

A third field is resistance to three body abrasion associated with pumping particle loaded fluids in the oil and gas industry, offshore power sectors, mining and mineral processing industries.

The possible applications of the coating in accordance with the present invention are not limited to those cited above. The coating can provide improved durability and functionality under any reciprocating loaded wear event.

Referring now to FIG. 1, there is illustrated apparatus which can be used to form a coating in accordance with the invention.

The apparatus is provided as a closed field unbalanced magnetron sputter ion plating apparatus in which there is provided a chamber 2 in which a vacuum can be created and a holder 4 which is provided to be rotatable about axis 6. On the external, side walls 8 of the holder, there are provided the substrates to be coated as the holder is rotated. Facing towards said substrates, at the periphery of the chamber, are provided a plurality of magnetrons 10 which can be provided in a configuration so as to form a closed field such that, for example, the magnetic configuration of adjacent magnetrons is such that the magnetic polarity of one magnetron is the reverse to that of adjacent magnetrons so as to create a magnetic field 12 within the chamber which encourages the material sputtered from the magnetron targets, to be deposited towards the substrates to be coated on the holder 4. Alternatively, or in addition, magnet arrays can be inserted between adjacent magnetrons so as to provide the required magnetic field configuration.

The targets of the magnetrons can be provided of the required material to form the coatings on the substrates. Typically the magnetrons are operated in a predesignated sequence so as to deposit the required material at the required time so as to form the multilayered coating as desired. Furthermore, appropriate gas or gases can be introduced into the chamber during the coating process, and during the application of particular materials so as to form the coating material to be applied.

In accordance with the invention, at least one of the magnetron having a metal target is first operated, so as to deposit the metal layer onto the substrate surface. Thereafter, at least one further magnetron is operated and gas introduced so as to deposit a ceramic material layer onto the metal layer, followed by a metal alloy layer and so on until the final coating is formed of the plurality of metal and ceramic layers.

The use of a ‘Shape Memory Alloy (SMA)’ material as part of the multilayer coating system, utilises the super-elastic properties of the ‘shape memory alloy’ to provide additional resistance to dynamic, reciprocating, loads as might be observed during ballistic impact, erosion or cyclic fatigue loadings.

Thus, the current invention permits the accepted wear resistance of multilayered coatings to be enhanced under dynamic impact conditions through the incorporation of ‘shape memory alloy’ metallic layers which provide super-elastic properties to the multilayer system.

1-32. (canceled)

33. A wear resistant coating for a surface of a substrate, said coating having a plurality of alternating layers of metallic and ceramic materials, the metallic layers having high ductility and super-elastic properties.

34. A coating according to claim 33 wherein the said coating consists of at least: four layers.

35. A coating according to claim 33 wherein at least one of the metallic layers is formed from a ‘shape memory alloy’.

36. A coating according to claim 33 wherein the ceramic layers are any, or any combination, of a boride, carbide, nitride or oxide of metals from groups 4, 5 or 6, and/or aluminium and/or silicon.

37. A coating according to claim 33 wherein the coating has a metallic layer in the form of a metal alloy layer and at least one ceramic layer formed from boride, carbide, nitride or oxide.

38. A coating according to claim 33 wherein the metallic material layer comprises an NiTi alloy.

39. A coating according to claim 33 wherein the metallic material layer is formed from elements selected from nickel, titanium, chromium, aluminium, platinum, hafnium, zirconium, cobalt, copper, and/or yttrium.

40. A coating according to claim 33 wherein the ceramic used is a boride, carbide, nitride or oxide of one of the alloying elements included in the metallic layer material.

41. A coating according to claim 40 wherein an interfacial ceramic layer is deposited that is a boride, carbide, nitride or oxide of one of the alloying elements included in the metallic layer material.

42. A coating according to claim 33 wherein the thickness of the ceramic layer(s) lies in the range 0.1 to 5.0 μm, preferably 0.3 to 3.0 μm.

43. A coating according to claim 33 wherein the ceramic layer thickness is below the critical thickness of ceramic brittle fracture, defined as:
$${h}_{c} = \frac{E {ϒ}_{s}}{2 f \cdot {σ}^{2}}$$
where E is the ceramic elastic modulus, Ys is the fracture surface energy for the ceramic, φ is the maximum tensile stress generated in the ceramic layers as a result of impact loading, and f is a geometric factor related to the contact geometry.

44. A coating according to claim 43 wherein the geometric factor, f, is 16 for a 1 μm thick ceramic layer with a modulus of 300 GPa.

45. A coating according to claim 33 wherein the ceramic layer is itself a multiplicity of sub-layers.

46. A coating according to claim 45 wherein said sub-layers are of different ceramic composition and the ceramic layer exhibits a super-lattice structure, which improves both its hardness and fracture resistance.

47. A coating according to claim 35 wherein the shape memory alloy layer thickness is between 0.5× and 2.0× the ceramic layer thickness.

48. A coating according to claim 33 wherein the plurality of layers extends to 25 repeat metal plus ceramic bi-layers, one of which is a metallic adhesion layer.

49. A coating according to claim 33 wherein the metallic layer has a thickness between 0.3 and 3.0 μm.

50. A method of forming an elastic coating on a substrate said method including the steps of applying a plurality of layers of ceramic material and a plurality of layers of metallic material and wherein said layers of ceramic material alternate with the layers of metallic material as the coating is formed.

51. A method according to claim 50 wherein a closed field, unbalanced magnetron sputter ion plating (CFUBMSIP) method is used.
